(19) United States
(12) Patent Application Publication
(10) Pub. No.: US 2016/0368613 A1
(43) Pub. Date: Dec. 22, 2016

(54) AIRCRAFT STRUCTURE WITH SOLAR ENERGY CAPTURE CAPACITY

(71) Applicants: AIRBUS GROUP SAS, Blagnac (FR); AIR BUS OPERATIONS (S.A.S), Toulouse (FR)

(72) Inventors: Bertrand RIVES, TOULOUSE (FR); Gilles PERES, TOULOUSE (FR); Alain PORTE, COLOMIERS (FR)

(73) Assignees: Airbus Group SAS, Blagnac (FR); Airbus Operations (S.A.S.), Toulouse (FR)

(21) Appl. No.: 14/900,282

(22) PCT Filed: Jun. 27, 2014
(86) PCT No.: PCT/EP2014/063761

§ 371 Date: Dec. 21, 2015

(30) Foreign Application Priority Data
Jun. 28, 2013 (FR) 1356246

(51) Int. Cl. B64D 33/00; H01L 31/049; H01L 31/18; H01L 31/0392

(52) U.S. Cl. CPC B64D 33/00; H01L 31/03926; H01L 31/049; H01L 31/1876; B64D 2211/00

(57) ABSTRACT

An aircraft structure (10), in particular the fuselage, nacelles or wings, includes, over all or part of an outer surface (21) that may undergo lightning impacts, a layer of flexible polymer (30), a photovoltaic film (40) and a protective layer (50) protecting the photovoltaic film. This aircraft structure primarily has a solar energy capture capacity making it possible to meet the needs of an aircraft as well as an ability to protect against the effects of lightning.

### FIELD OF THE INVENTION

The present invention relates to the energy supply for aircraft. More particularly, it relates to an aircraft structure with solar energy capture capacity.

The invention offers a particular advantage for aircraft structures made of composite material.

### STATE OF THE ART

The current aircrafts comprise an embedded electrical power source intended to produce electrical energy on board the latter to make it possible to power, whether on the ground or in flight, different systems consuming electrical power.

These systems, generally remote from one another and from the electrical power source, are distributed throughout the aircraft, from the cockpit to the tail of the airplane, by passing through the wings.

Among the systems that require an electrical power supply remote from the electrical power source, there are, by way of illustrative example, the flashing lights situated at the ends of the wings.

To reach and individually power each of the systems, bundles of electrical cables are run from the electrical power source to each system.

Such a network of bundles of electrical cables is obviously a source of penalty for the aircraft, whether in terms of costs or weight.

Furthermore, the arrangement of such a network of bundles of electrical cables presents the drawbacks of complex implementation, ofincreased complexity in the operations of installing and maintaining these bundles of electrical cables.

Furthermore, since there is a relatively high number of these systems and they are heavy energy consumers, the electrical power source has to supply a not inconsiderable electrical power, which is also a source of penalty in terms of costs and weight.

### EXPLANATION OF THE INVENTION

The objective of the present invention is specifically to define an aircraft structure with energy capture capacity, with a weight penalty at most equivalent to the existing solutions and that has performance levels at least equivalent to the existing solutions.

To this end, the present invention proposes coating an aircraft structure with a coating with electrical conductivity property deposited on its outer surface. The outer surface is here defined as the surface facing the environment outside the aircraft, in other words the surface likely to be subjected to lightning strikes.

More particularly, there is proposed, according to the present invention, an aircraft structure, with solar energy capture capacity, in which at least a part of the outer surface is coated with a photovoltaic film.

A photovoltaic film should be understood to mean a layer of small thickness compared to the other two dimensions (length and width). This photovoltaic film is a flexible layer, that is to say a non-rigid layer. This film is made up of photovoltaic cells configured in the form of independent photovoltaic modules to deliver as output a direct electrical current and/or a voltage when they are subjected to an incident solar radiation.

The photovoltaic modules are linked together in series or parallel, and arranged one alongside the other so as to form the photovoltaic film.

The photovoltaic cell consists of a number of layers, one of which is an electrode with electrical conduction capacity. This electrode advantageously makes it possible to collect and transfer the electrical charges.

This electrode is preferentially a layer of silver, copper or aluminum.

The capture of the solar energy by an aircraft structure provided with such a photovoltaic film and its transformation into electricity offers a not inconsiderable input from an ecological point of view.

Thus, certain systems will advantageously be able to be powered via a source of energy originating from the capture of solar energy via the aircraft structure according to the invention, placed in proximity to said systems. Such a way of powering these systems, for example those furthest away from an electrical power source of the aircraft, makes it possible to reduce the electrical wiring.

Consequently, a photovoltaic film on an aircraft structure offers a solar energy capture capacity serving the needs of the aircraft, without giving rise to a penalty in terms of weight or complex implementation.

In addition to a solar energy capture capacity, the photovoltaic film offers the capacity to transfer the electrical charges to be dissipated more quickly and effectively than the current solutions, in the event of a lightning strike on said aircraft structure.

The use of a photovoltaic film on the surface of the aircraft structure makes it possible to obtain an effective protection of said aircraft structure against the effects of lightning without causing any degradation of the surface quality, as it is the case for the existing aircraft structures that require a metal mesh. In effect, the photovoltaic film has a uniform and constant thickness unlike a metal mesh whose thickness is intermittent.

Another advantage of the use of a photovoltaic film on the surface of the aircraft structure lies in the production constraints.

In effect, the production constraints associated with the surface quality of the structure, because of a constant thickness of the photovoltaic film, are reduced compared to those of a surface with mesh.

The result thereof, compared to the traditional solutions offered by the prior art for protection against lightning, is a cycle gain through the reduction of the number of and time required for the manufacturing operations, and simplified maintenance.

The addition to the structure of a photovoltaic film makes it possible to meet the requirements of energy production and of production against lightning.

This extremely advantageous result is obtained in the absence of traditional metal mesh proposed by the prior art.

The aircraft structure is also advantageously stripped of decorative paint layer, in particular for the non-customized areas, such as, for example, the aircraft wings.

The use of such a photovoltaic film is suited to any aircraft structure, whether made of metallic material or of composite material.

A structure made of composite material should be understood to be a structure produced from mineral or organic fibers, for example glass fibers, aramid fiber or carbon fiber, held in a hard organic matrix, of epoxy for example.

According to particular embodiments, the invention also addresses the following features, implemented separately or in each of their technically operative combinations. At least some of these features aim at additional objectives of the invention. In particular, the invention aims for the top surface of the aircraft structure, that facing the outside environment, to be as smooth and bright as in the absence of the standard decorative layer in current aircraft.

In particular embodiments of the invention, the aircraft structure comprises a flexible polymer layer between the outer surface and the photovoltaic film.

The flexible polymer layer is a non-rigid layer which makes it possible to guarantee the deformability of the assembly in the thermomechanical stress conditions of the structure of the aircraft.

Such a layer is, for example, formed from elastomer matrices, polysulfone amide matrices (known by the acronym PSA) or so-called hot/melt elastomers that advantageously allow adhesion to the outer surface and to the photovoltaic film while guaranteeing the viscoelastic characteristics sought.

The flexible polymer layer is advantageous from an aerodynamic point of view. In effect, such a layer can be applied in a single operation to a plurality of assembled aircraft structures, thus making it possible to remedy the geometrical differences of assemblies, such as, for example, the tolerances of the holes and fastenings, and thus avoiding all spurious vortices in the laminar air flow sought in order to minimize fuel consumption.

In particular embodiments of the invention, to improve the electrical conductivity in the flexible polymer layer, said polymer layer includes electrically conductive particles.

In an exemplary embodiment, the electrically conductive particles are chosen from a group comprising graphene, carbon fibers, metal nanowires or carbon nanotubes, a mixture of these particles or any other conductive pigment (metal, polymer, etc.).

According to an advantageous feature of the invention, in order to guarantee the durability and resistance to the effects of lightning, the polymer layer has a thickness of between 40 and 110 μm, preferably 80 μm. Such a thickness also makes it possible not to penalize the aircraft structure in terms of weight.

Such a polymer layer also presents advantages in terms of:
aerodynamics,
compatibility with current environmental requirements, resistance to chemical and environmental attacks specific to an outer aircraft structure,
application and re-application on the outer surface in case of repair.

In particular embodiments of the invention, the aircraft structure comprises a protective layer covering the photovoltaic film.

The protective layer is a layer suitable for guaranteeing the life-expectancy of the aircraft structure in the environmental stress conditions specific to aircraft.

The protective layer coats the photovoltaic film in order to protect it against corrosion, against external degradations, etc.

Such a protective layer is for example formed from polyurethane resins with a high number of functional groups ensuring a high degree of cross-linkage.

The protective layer exhibits brightness and orange skin characteristics conforming to all the customized areas of aeronautical liveries.

According to an advantageous feature of the invention, to make it possible for the photovoltaic film to receive the light radiations and conserve its photovoltaic properties, the protective layer is transparent to the ultraviolet rays in the useful frequency band.

In particular embodiments of the invention, the photovoltaic cells have a substantially identical geometrical form, preferentially square.

In particular embodiments of the invention, the photovoltaic cells have a substantially identical geometrical form, preferentially triangular.

In particular embodiments of the invention, the photovoltaic cells have a substantially identical geometrical form, preferentially hexagonal, because this form improves the capacity of the photovoltaic film to accept deformations, in addition to the same acceptance capacity of the flexible polymer layer.

In a preferred exemplary embodiment, to facilitate the repairing of the photovoltaic film, each cell has a size substantially of the order of 200*200 mm.

In particular embodiments of the invention, the photovoltaic film has a thickness of between 300 and 1000 μm, preferably of approximately 400 μm.

This thickness, greater than the typical thicknesses of the photovoltaic cells (which are of the order of a hundred or so μm), plays a not inconsiderable role in the protection of the aircraft structure to lightning strikes because it makes it possible to increase the transfer of the electrical charges during a lightning strike on the aircraft structure.

The overdimensioning in terms of thickness of the photovoltaic film is primarily an overdimensioning in terms of thickness of the electrodes with electrical conduction capacity of the photovoltaic cells.

The thickness of said electrodes is chosen such that the surface impedance is less than 2 mΩ/□±20%, so as to guarantee the discharging of the electrical charges linked to a lightning strike in the best conditions for the structure of the aircraft.

In particular embodiments of the invention, the aircraft structure coated over at least a part of its outer surface with at least one photovoltaic film is a fuselage, an engine nacelle or a wing of the aircraft.

According to another aspect, the present invention relates to an aircraft comprising an aircraft structure meeting one or more of the above features.

According to another aspect, the present invention relates to a method for manufacturing an aircraft structure, according to which a photovoltaic film is applied over at least a part of an outer surface of said aircraft structure meeting one or more of the above features.

The application of this photovoltaic film entails few specific operations, which can be incorporated in a more general process of application of the conventional coating layers on the outer surface of the body of the aircraft.

This manufacturing method is easily adapted to the protection of the outer surface against the effects of lightning.

The result thereof, compared to the current solutions for protection against lightning strikes for example, is a cycle gain through a reduction in the number of and time required for the installation and inspection operations, and simplified maintenance.

This application is preferentially performed on at least the outer surface of the fuselage, of the engine nacelles or of the wings of the aircraft.

In particular implementations of the invention, the application of the photovoltaic film can be performed by techniques that are conventional in themselves, for example by film coating.

In particular implementations of the invention, a flexible polymer layer is applied to the outer surface of the aircraft structure, then the photovoltaic film is applied to the flexible polymer layer.

In particular implementations of the invention, a protective layer is applied onto the photovoltaic film.

In particular implementations of the invention, the application of the flexible polymer and protection layers can be performed by techniques that are conventional in themselves, for example of the spray or inkjet type, etc., and be followed by a drying step, whether it be drying in ambient air, controlled drying, drying at predefined temperature and relative humidity, or accelerated drying by ultraviolet lamp.

In particular implementations of the invention, the application of the flexible polymer layer, respectively of the protective layer, is first preceded by a step of preparation of the outer surface of the aircraft structure, respectively of the photovoltaic film.

In particular implementations of the invention, the application of the photovoltaic film is previously preceded by a step of preparation of the surface on which it will rest.

### DESCRIPTION OF THE FIGURES

The invention will now be more specifically described in the context of particular embodiments, which are in no way limiting, represented in FIGS. 1 to 4, in which:

FIG. 1 illustrates a cross-sectional view of a multilayer assembly applied onto the outer surface of the skin of an aircraft fuselage,

FIG. 2 illustrates a plan view of a mosaic of photovoltaic cells having a square geometrical form,

FIG. 3 illustrates a plan view of a mosaic of photovoltaic cells having a triangular geometrical form,

FIG. 4 illustrates a plan view of a mosaic of photovoltaic cells having a hexagonal geometrical form.

### DESCRIPTION OF A PREFERRED EMBODIMENT

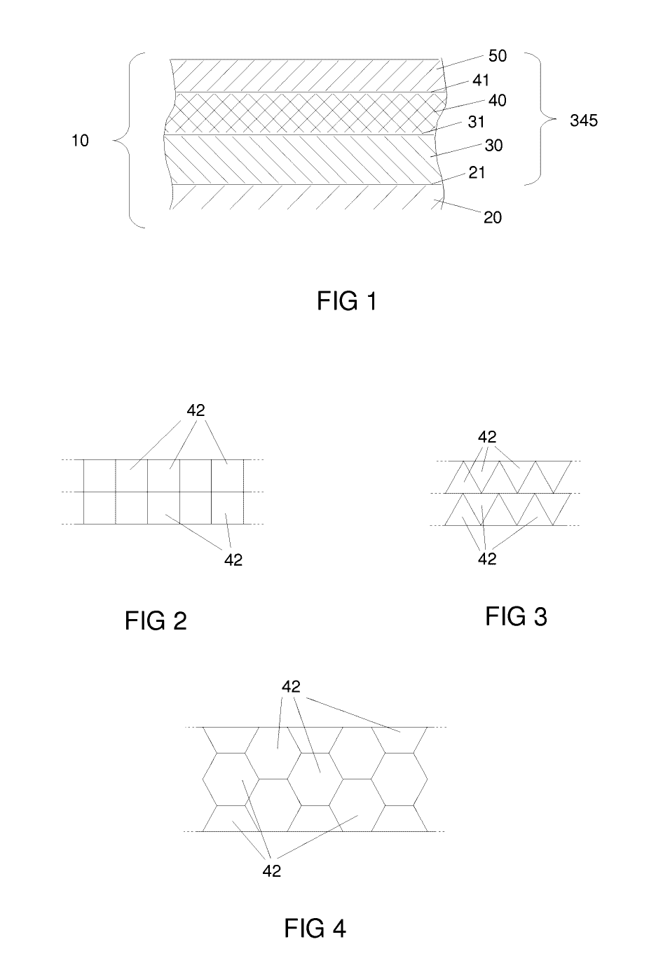

An exemplary aircraft structure 10 according to the invention is illustrated schematically in FIG. 1. FIG. 1 shows a locally flat aircraft structure by way of illustration without this being in any way limiting of the invention.

In this FIG. 1, the relative thicknesses of the different layers of this aircraft structure have been chosen by way of example, and so as to clearly show each of these layers, and these relative thicknesses should in no way be considered as limiting or even representative of a real multilayer assembly.

An aircraft structure 10 according to the invention is made of composite material and mainly comprises a structural part 20 comprising mineral or organic fibers held in a hard organic resin.

For example, such a structural part 20 comprises stacked plies of glass, Kevlar® or carbon fiber, woven or unidirectional, held in a matrix of a polymer material such as an aramid.

The aircraft structure described is for example a fuselage without this choice being limiting on the invention.

The fuselage comprises, on a surface 21, called outer surface, of the structural part 20 of one side of said fuselage on which electrical charges are likely to build up and/or a lightning strike is likely to occur, a multilayer assembly 345. This multilayer assembly 345 is applied instead of the outer decorative paint.

This multilayer assembly 345 comprises a plurality of layers 30, 40, 50 for solar energy harvesting and for the protection of the aircraft against the effects of lightning and corrosion. The multilayer assembly 345 notably comprises, arranged one on top of the other on the outer surface 21 of the structural part 20 of the fuselage 10, three successive layers.

A first layer, called non-rigid polymer layer 30, covers, wholly or partly, the outer surface 21 of the structural part 20. This non-rigid polymer layer has, for example, a thickness of between 40 and 110 μm, preferably 80 μm. In an exemplary embodiment, the non-rigid polymer layer is specific mastic for aeronautical applications, elastomers, PSA acrylic matrices, or even hot-melt elastomers.

A second layer, called photovoltaic film 40, covers a surface 31 of the non-rigid polymer layer, opposite a surface covering the outer surface 21 of the structural part.

The photovoltaic film 40 is flexible and is made up of a plurality of photovoltaic cells 42 linked in series or in parallel.

The production principle of the photovoltaic cells is well known from the prior art and will not be described here.

The photovoltaic cells 42 used are preferentially of 2nd or 3rd generation type.

In exemplary embodiments, the photovoltaic cells 42 have a square, triangular or hexagonal geometrical form, as illustrated in FIGS. 2 to 4.

The photovoltaic film 40 has a thickness of between 300 and 1000 μm, preferably 400 μm. This thickness is very much greater than the thickness of the conventional photovoltaic cells in order to increase the transfer of the electrical charges in the event of a lightning strike on the aircraft structure.

The flexible polymer layer 30 positioned between the fuselage and the photovoltaic film 40 advantageously makes it possible to absorb the differential expansions between said fuselage and said photovoltaic film which can occur in conditions of use of the aircraft.

In a variant embodiment, to increase the transfer of the electrical charges in the event of a lightning strike on the aircraft structure, the flexible polymer layer 30 includes electrically conductive particles, of graphene, carbon nanotubes and other such types.

A top layer, called protective layer 50, covers a surface 41 of the photovoltaic film 40. The photovoltaic film 40 is thus inserted between the flexible polymer layer 30 and the protective layer 50.

The protective layer 50 advantageously makes it possible to withstand the external attacks that the aircraft can undergo in conditions of use.

This protective layer has a thickness of between 10 and 80 μm. In an exemplary embodiment, the protective layer is of lacquer type.

The protective layer consists, for example, of polyurethane resins with a high number of functional groups ensuring a high degree of cross-linkage.

In a preferred embodiment of the protective layer, said protective layer is transparent and resistant to ultraviolets in order to allow the photovoltaic film to ensure a good absorption of the solar radiation.

In a preferred embodiment of the protective layer, said protective layer 50 is a layer that ensures a good absorption of the solar radiation.

The outer surface 21 of the structural part 20 is not mandatorily all covered by the multilayer assembly 345, certain areas that are exposed little or not at all to the risk of lightning being able to be not protected or protected by other means, the description being limited to a part of the outer surface 21 protected according to the principle of the invention.

The application of the multilayer stacking 345 is performed on the outer surface 21 of the structural part 20 of the fuselage of the aircraft.

The application of these different layers on the outer surface 12 of the fuselage 11 of the aircraft requires only a few specific operations compared to the current solutions, among other things for the protection of an aircraft against lightning strikes.

The three layers 30, 40, 50 are applied in succession one on top of the other.

The application of the flexible polymer layer 30, respectively of the protective layer 40, can be performed by any technique that is conventional in itself, for example by inkjet, the outer surface 21 of the fuselage, respectively of the surface 41 of the photovoltaic film, having first been subjected to the conventional surface preparation operations necessary for this purpose.

The application of the photovoltaic film 40 onto the surface 31 of the flexible polymer layer on which it will rest can be performed by any technique that is conventional in itself, for example by film coating.

First, an operation of preparation of the surface 31 of the polymer layer is performed.

The proposed invention advantageously makes it possible to produce an aircraft structure that is protected against the effects of lightning, with little penalty in terms of weight of the aircraft, and without penalizing the outer esthetic appearance thereof. It also advantageously makes it possible to capture ambient solar energy for the internal needs of aircraft.

1-9. (canceled)

10. An aircraft structure comprising, over all or part of an outer surface, a photovoltaic film, wherein said aircraft structure comprises a flexible polymer layer between the outer surface and the photovoltaic film.

11. The aircraft structure as claimed in claim 10, wherein the flexible polymer layer comprises electrically conductive particles.

12. The aircraft structure as claimed in claim 10, wherein the flexible polymer layer has a minimum thickness of 80 μm.

13. The aircraft structure as claimed in claim 10, further comprising a protective layer covering the photovoltaic film.

14. The aircraft structure as claimed in claim 10, wherein the photovoltaic film consists of a set of photovoltaic cells of the same geometrical form.

15. The aircraft structure as claimed in claim 10, wherein the photovoltaic film has a thickness of between 300 and 1000 μm.

16. The aircraft structure as claimed in claim 15, wherein the photovoltaic film has a thickness of approximately 400 μm.

17. A method for manufacturing an aircraft structure as claimed in claim 10, which comprises applying a photovoltaic film over at least a part of an outer surface of said aircraft structure, wherein a flexible polymer layer is applied to the outer surface, prior to the application of the photovoltaic film.

18. The method for manufacturing an aircraft structure as claimed in claim 17, wherein the application of the photovoltaic film is performed by film coating on the outer surface.

19. The method for manufacturing an aircraft structure as claimed in claim 17, wherein the photovoltaic film is covered with a protective layer.
